(19) United States
(12) Patent Application Publication
(10) Pub. No.: US 2023/0020146 A1
(43) Pub. Date: Jan. 19, 2023

(54) CONTROL APPARATUS, DEGRADATION ESTIMATING SYSTEM, CONTROL METHOD, AND COMPUTER PROGRAM

(71) Applicant: GS YUASA INTERNATIONAL LTD., Kyoto-shi, Kyoto (JP)

(72) Inventor: Yasunori MIZOGUCHI, Kyoto-shi, Kyoto (JP)

(21) Appl. No.: 17/782,218

(22) PCT Filed: Dec. 4, 2020
(86) PCT No.: PCT/JP2020/045250

§ 371 Date: Jun. 3, 2022

(30) Foreign Application Priority Data
Dec. 6, 2019 (JP) 2019-221579

(51) Int. Cl. H02J 7/00; G01R 31/392; G01R 31/389; G01R 31/3842; H01M 10/06; H01M 10/44; H01M 10/48

(52) U.S. Cl. CPC H02J 7/0069; G01R 31/392; G01R 31/389; G01R 31/3842; H02J 7/0063; H02J 7/0048; H02J 7/005; H02J 7/0013; H01M 10/06; H01M 10/441; H01M 10/482

(57) ABSTRACT

A control apparatus (1) includes a charge controller that, by using power when a lead-acid battery (3) or a lead-acid battery module (4) including a plurality of lead-acid batteries is discharged, performs refresh charge of another lead-acid battery (3) or another lead-acid battery module (4).

### TECHNICAL FIELD

The present invention relates to a control apparatus, a degradation estimating system, a control method, and a computer program for controlling charge of a lead-acid battery or a lead-acid battery module.

### BACKGROUND ART

A lead-acid battery is used in various applications in addition to on-vehicle applications and industrial applications, For example, a secondary battery (energy storage device) such as an in-vehicle lead-acid battery is mounted on a moving body such as a vehicle such as an automobile, a motorcycle, a forklift, or a golf car, and is used as a power supply source to a starter motor at the time of starting an engine and a power supply source to various electric components such as a light.

Industrial lead-acid batteries are used as the power supply source to an emergency power supply or an uninterruptible power supply (UPS). In a power storage system or the like used for power leveling of sunlight, wind power, or the like, a large number of lead-acid batteries are connected in parallel and in series to construct a large-scale power storage system. The industrial lead-acid batteries are sometimes referred to as stationary lead-acid batteries in order to distinguish the in vial lead-acid batteries from in-vehicle lead-acid batteries.

The lead-acid batteries used for the power leveling are often operated in a partially charged state so as to be able to store surplus power. When the lead-acid battery is continuously used in the partially charged state, lead sulfate becomes coarse, and causes degradation called sulfation, which is difficult to be charged and discharged. Accordingly, when the lead-acid battery is used in the partially charged state, charge (refresh charge) is often performed every several days to several weeks until the lead-acid battery is fully charged (for example, Patent Document I or the like).

### PRIOR ART DOCUMENT

### Patent Document

Patent Document 1 JP-A-2003-346911

### SUMMARY OF THE INVENTION

### Problems to be Solved by the Invention

The refresh charge often requires external power, which is problematic in terms of cost and convenience.

An object of the present invention is to provide a control apparatus, a degradation estimating system, a control method, and a computer program that perform the refresh charge without requiring the external power.

### Means for Solving the Problems

A control apparatus according to one aspect of the present invention includes a charge controller that, by using power when a lead-acid battery or a lead-acid battery module including a plurality of lead-acid batteries is discharged, performs refresh charge of another lead-acid battery or another lead-acid battery module.

A degradation estimating system according to another aspect of the present invention includes the above-described control apparatus and a terminal that transmits a current, a voltage, or an internal resistance to the control apparatus, and the control apparatus transmits the degree of degradation estimated by the estimation unit to the terminal.

A control method according to still another aspect of the present invention performs, by using power when a lead-acid battery or a lead-acid battery module including a plurality of lead-acid batteries is discharged, refresh charge of another lead-acid battery or another lead-acid battery module.

A computer program according to yet another aspect of the present invention causes a computer to execute processing for performing, by using power when a lead-acid battery or a lead-acid battery module including a plurality of lead-acid batteries is discharged, refresh charge of another lead-acid battery or another lead-acid battery module.

### BRIEF DESCRIPTION OF THE DRAWINGS

FIG. 1 is a block diagram illustrating an example of a configuration of a degradation estimating system according to a first embodiment.

FIG. 2 illustrates an example of a degradation level curve.

FIG. 3 is an explanatory view of a discharge curve.

FIG. 4 is a flowchart illustrating a procedure of processing when a controller performs adjustment discharge on a battery, performs refresh charge on another battery, and corrects a state of charge (SOC).

FIG. 5 is a flowchart illustrating a procedure of processing when the controller performs the adjustment discharge on the battery, performs the refresh charge, and performs the correction of the SOC, estimation of a degradation level, and adjustment of a load.

FIG. 6 is a graph illustrating results of examining an internal resistance of each battery when batteries 1 to 6 with reduced capacities are deeply discharged until the estimated SOC reaches 30%.

FIG. 7 is a graph illustrating results of examining the internal resistances of the batteries 1 to 6 with reduced capacities in a fully charged state.

FIG. 8 is a block diagram illustrating a configuration of a degradation estimating system according to a second embodiment.

FIG. 9 is a schematic diagram illustrating an example of a learning model.

FIG. 10 is a flowchart illustrating a procedure of learning model generation processing by the controller.

FIG. 11 is a flowchart; illustrating a procedure of processing in which the controller performs the adjustment discharge on the battery, performs the refresh charge, and estimates a degree of degradation of the battery.

FIG. 12 is a schematic diagram illustrating an example of the learning model.

FIG. 13 is a flowchart illustrating a procedure of processing in which the controller performs the adjustment discharge on the battery, performs the refresh charge, and estimates the degree of degradation.

### MODE FOR CARRYING OUT THE INVENTION

(Outline of Embodiment)

A control apparatus according to an embodiment includes a charge controller that performs, by using power when a lead-acid battery or a lead-acid battery module including a plurality of lead-acid batteries is discharged, refresh charge of another lead-acid battery or another lead-acid battery module.

According to the above configuration, by using power output when the lead-acid battery or the lead-acid battery module is discharged, the refresh charge of the another lead-acid battery or the anther lead-acid battery module is performed. The refresh charge can be performed without requiring external power. The power cost due to the refresh charge can be reduced, and even when the power storage system is independent from the power system, the refresh charge and maintenance such as the correction of the SOC or the estimation of the degradation state can be simultaneously performed based on the transition of the voltage during the discharge or the like.

The control apparatus may he a battery control apparatus that controls charge-discharge of the lead-acid battery included in the power storage system or the like, or may control the battery control device by remote operation.

The control apparatus may include an SOC correction unit that corrects an estimated value of an SOC of the lead-acid battery or the lead-acid battery module based on a residual capacity derived from a current and transition of a voltage when the lead-acid battery or the lead-acid battery module is discharged.

At this point, the SOC represents residual capacity Cs with respect to full charge capacity C_{full} in percentage, and is calculated by the following equation.

SOC=Cᵣ/C_{full}×100[%]

According to the above configuration, the residual capacity is obtained as described later based on a temporal transition of the current and the voltage in the case of the discharge. When the SOC is estimated based on a current integration method or the like, because a loss due to a side reaction during the charge or self-discharge, an error is generated in the estimated SOC. An estimation error may be accumulated due to a detection error of a current sensor or the like. The estimated SOC is corrected by the SOC (hereinafter, referred to as actually measured SOC) based on the residual capacity derived from the above history. For example, the estimated SOC is replaced with the actually measured SOC. Thereafter, the SOC is estimated based on, for example, the current integration method with the replaced actually measured SOC as a reference. The average value of the estimated SOC and the actually measured SOC may be used as the updated SOC.

The control apparatus may include an estimation unit that estimates a degree of degradation of the lead-acid battery or the lead-acid battery module based on an internal resistance or conductance derived in a case of the discharge.

It is considered that when positive electrode softening progresses, the coupling between the active material particles constituting the positive electrode material becomes weak to increase the resistance of the positive electrode material. However, in the fully charged state, namely, when almost all of the active material is conductive PbO₂, an increase amount of the internal resistance is not large, but the ratio of the internal resistance caused by the positive electrode softening to the internal resistance of the entire battery is very small. At an end of a life, the internal resistance of the entire battery is determined by a corrosion state of a positive electrode current collector, a decrease in electrolyte solution, and the like. For example, the corrosion of the current collector is slight, but the remaining life of the battery cannot be accurately determined when the positive electrode softening progresses. When the battery is deeply discharged, insulating PbSO₄ is further generated at a position where the coupling between the active material particles in the positive electrode is weakened due to softening, so that the resistance of the positive electrode material is significantly increased. That is, in the deep discharge state, the battery internal resistance increases according to the degree of progress of the positive electrode softening. The increase in resistance due to the corrosion of the current collector or the like affects the internal resistance of the battery regardless of the discharge state.

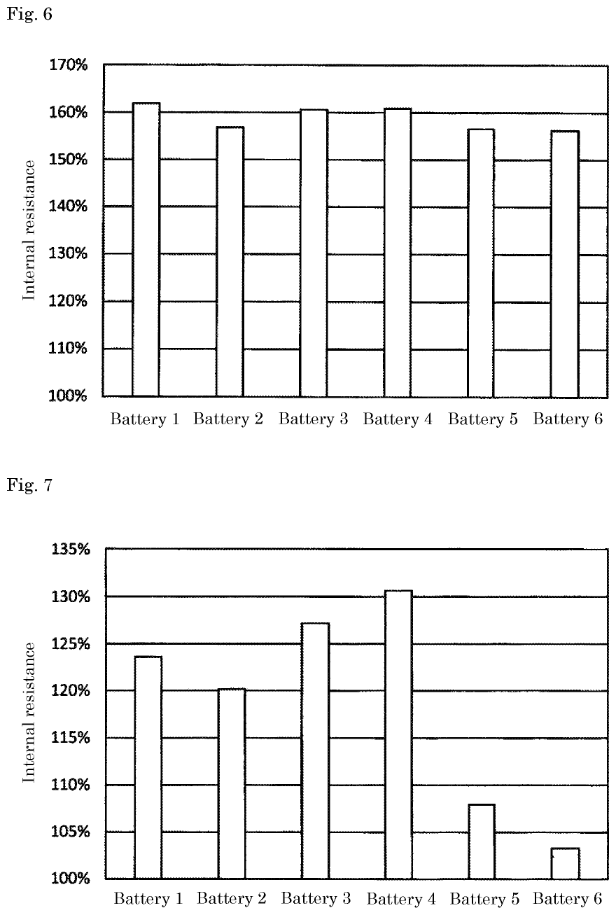

The present inventor has found that the degree of degradation can be satisfactorily estimated based on the internal resistance or conductance when the deep discharge is performed even in the case where the lead-acid battery is used in an application in which the life is reached due to the positive electrode softening like the power storage system (see FIGS. 6 and 7).

According to the above configuration, it is possible to obtain information about the degradation state of the lead-acid battery in consideration of many degradation modes such as the positive electrode softening, the corrosion of the current collector, and the decrease in electrolyte solution based on the internal resistance when the discharge is performed to perform the refresh charge, and the degree of degradation can be satisfactorily estimated.

The discharge is preferably performed within a range of the SOC (estimated SOC) of 0% to 40%, namely, until the SOC reaches less than or equal to 40%, or until the SOC reaches a voltage corresponding thereto. When the SOC exceeds 40%, the increase amount of internal resistance due to the positive electrode softening is small, and the degradation cannot be accurately detected. More preferably SOC is 40%, and still more preferably SOC is 30%.

In the control apparatus, the internal resistance may be at least one of: a first internal resistance derived based on the current and the voltage immediately before end of the discharge and a current and a voltage immediately after end of the discharge; a second internal resistance derived based on a current and a voltage immediately before start of charge and a current and a voltage immediately after start of the charge; and a third internal resistance derived from a response when an AC voltage or an AC current is applied to the discharged lead-acid battery.

According to the above configuration, the internal resistance can be accurately derived.

A first internal resistance It is derived from the following Equation (1) when the first internal resistance R is paused after the discharge.

R=ΔV/ΔI=(V−V1)/(I2−I1) Equation (1)

Where, V1 is a voltage immediately before the end of the discharge, I1 is a current immediately before the end of the discharge,

V2 is a voltage immediately after the end of the discharge (at start of the pause), and I2 is a current immediately after the end of the discharge.

For example, the time immediately before the end of the discharge refers to 0.1 seconds, 1 second, 5 seconds, or 10 seconds before the end time of the discharge. In addition, for example, immediately after the end of the discharge refers to 0.1 seconds, 1 second, 5 seconds, 10 seconds, or the like after the end time of the discharge.

A second internal resistance R is derived from the following Equation (2) when the charge is performed after the pause.

R=ΔV/ΔI=(V4−V3)/(I4−I3) Equation (2)

Where, V3 is a voltage immediately before the charge is started (at the end of the pause), I3 is a current immediately before the charge is started.

V4 is a voltage immediately after the charge is started, and I4 is a current immediately after the charge is started.

For example, the time immediately before the start of the charge refers to 0.1 seconds, 1 second, 5 seconds, 10 seconds, or the like of the charge start time. In addition, for example, immediately after the start of the charge refers to 0.1 seconds, 1 second, 5 seconds, 10 seconds, or the like after the charge start time.

In the case where the charge is performed without pausing after the discharge

immediately after end of discharge=start of charge, and

discharge end time=immediately before charge start, so that it is calculated by the same equation as that for the first internal resistance or the second internal resistance. That is, the internal resistance R in this case is derived by the following Equation (3).

R=ΔV/ΔT=(V2−V1)/(I2−I1) Equation (3)

Where V1 is a voltage at the end of the discharge (immediately before the start of the charge), and I1 is a current at the end of the discharge.

V2 is a voltage immediately after the end of the discharge (at the start of the charge), and I2 is a current immediately after the end of the discharge.

For example, the third internal resistance is calculated in accordance with “JIS C 8715-1”.

An effective value Ua of the AC voltage is measured for a predetermined time (for example, between 1 second and 5 seconds) when an effective value Ia of the AC current having a predetermined frequency (for example, a frequency between 1 Hz and 1 MHz) is applied to a battery cell. Alternatively, the effective value Ia of the AC current is measured for a predetermined time (for example, between 1 second and 5 seconds) when the effective value Ua of the AC voltage having the predetermined frequency (for example, a frequency between 1 Hz and 1 MHz) is applied to the battery cell.

An AC internal resistance Rac is obtained by the following equation.

Rac=Ua/Ia

Where, Rac is an AC internal resistance (Ω), Ua is an effective value (V) of an AC voltage, and Ia is an effective value (A) of an AC current

All voltage measurements use terminals that are independent; of the contacts used for energization.

When the measurement is performed with an alternating current, an alternating peak voltage superimposed by current application is desirably less than 20 mV.

This method measures impedance in which a real component is approximately equal to the internal resistance at a defined frequency.

The internal resistance may be measured using a direct current as described in “JIS C 8704-1”, or may be a pulse impedance in addition to the DC resistance and the AC impedance derived from the charge-discharge data as described above.

The degree of degradation can also be estimated using conductance that is a reciprocal of resistance measured by a battery tester or the like.

In the control apparatus, the estimation unit may input the internal resistance or the conductance of a target lead-acid battery or lead-acid battery module to a learning model that outputs a degree of degradation to estimate the degree of degradation of the lead-acid battery or lead-acid battery module when the internal resistance or the conductance is input using the internal resistance or the conductance and a label data indicating the degree of degradation as teacher data.

According to the above configuration, the degree of degradation can be easily and accurately estimated.

In the control apparatus, when the current and voltage are input when the lead-acid battery or the lead-acid battery module is discharged, the estimation unit may estimate a degree of degradation of the lead-acid battery or the lead-acid battery module by inputting the acquired current and voltage to a learning model that outputs a degree of degradation.

According to the above configuration, the degree of degradation can he estimated without deriving the internal resistance.

The control apparatus may include a load adjustment unit that adjusts a load of each lead-acid battery or each lead-acid battery module according to the degree of degradation estimated by the estimation unit.

Sometimes a difference in the progress of the degradation of the lead-acid battery is generated due to the temperature of the installation location of the lead-acid battery, performance variation for each lead-acid battery, and the like. Each time the lead-acid battery is degraded, only a part of the lead-acid battery is required to he replaced, and the maintenance is complicated. When the positive electrode softening progresses, because the degradation state of the lead-acid battery cannot be correctly estimated by a conventional diagnosis based on the internal resistance in the fully charged state, there is a possibility that a part of the lead-acid battery exceeding the use limit is used in the state of being connected to the system.

According to the above configuration, based on the degree of degradation estimated using the internal resistance derived when the discharge is performed in order to perform the refresh charge, the control is performed such that the load of the lead-acid battery with early degradation is reduced while the load of the lead-acid battery with slow degradation is increased. The degradation rate of the lead-acid battery in the entire power storage system can be uniformly maintained to reduce the number of times of replacement of the lead-acid battery, and the risk that some lead-acid batteries are used beyond the limit can be reduced. Similarly, the load can also be adjusted for the lead-acid battery module.

A degradation estimating system according to another embodiment includes the above-described control apparatus and a terminal that transmits a current, a voltage, or the internal resistance to the control apparatus, and the control apparatus transmits the degree of degradation estimated by the estimation unit to the terminal.

According to the above configuration, the control apparatus can estimate the degree of degradation based on the current, the voltage, or the internal resistance or the conductance transmitted by the terminal, and notify the user of the lead-acid battery of the estimation result.

A control method according to still another embodiment performs refresh charge of a lead-acid battery or a lead-acid battery module using power when another lead-acid battery or another lead-acid battery module including a plurality of lead-acid batteries is discharged.

According to the above configuration, the refresh charge of the lead-acid battery or the lead-acid battery module is performed using power output when another lead-acid battery or another lead-acid battery module is discharged. The refresh charge can be performed without requiring external power. The power cost due to the refresh charge can be reduced, and even when the power storage system is independent from the power system, the refresh charge and maintenance such as the correction of the SOC or the estimation of the degradation state can he simultaneously performed based on the transition of the voltage during the discharge or the like.

A computer program according to yet another embodiment causes a computer to execute processing for performing refresh charge of a lead-acid battery or a lead-acid battery module using power when another lead-acid battery or another lead-acid battery module including a plurality of lead-acid batteries is discharged.

According to the above configuration, the refresh charge can be performed without requiring the external power. The power cost due to the refresh charge can be reduced, and the maintenance such as the refresh charge and the correction of the SOC or the estimation of the degradation state can be simultaneously performed even when the power storage system is independent; from the power system.

### First Embodiment

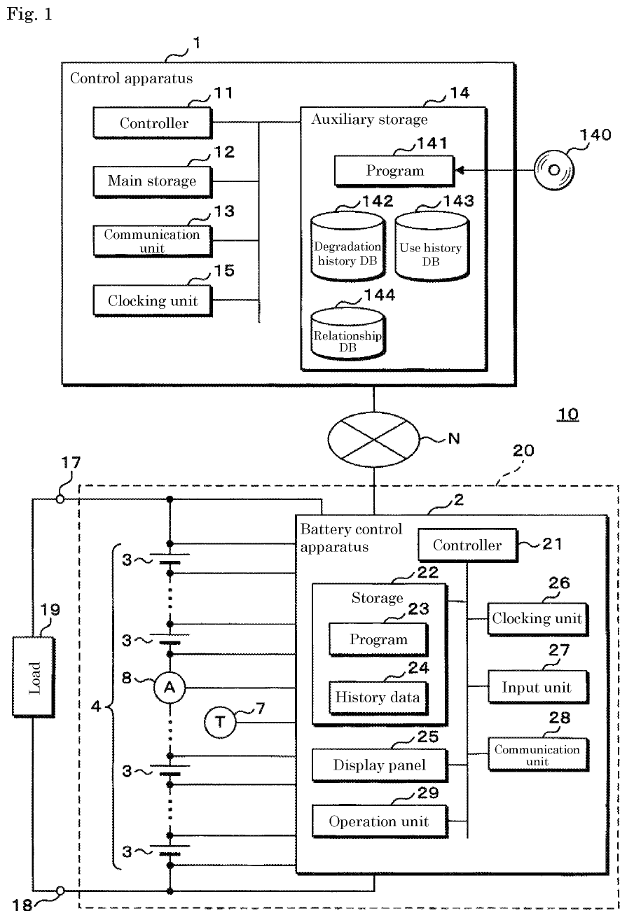

FIG. 1 is a block diagram illustrating an example of a configuration of a degradation estimating system 10 according to a first embodiment. In the degradation estimating system 10, a battery control apparatus 2 of a power storage system 20 is connected to a control apparatus 1 through a network N such as the Internet. The battery control apparatus 2 controls charge-discharge of a lead-acid battery (hereinafter, referred to as a battery) 3 and a lead-acid battery module (hereinafter, referred to as a battery module) 4. The control apparatus 1 controls adjustment discharge and refresh charge, which will be described later, of the battery 3 or the battery module 4 by the battery control apparatus 2. The control apparatus 1 also corrects the estimated SOC of the battery 3 or the battery module 4 to estimate the degradation. The battery 3 includes a container, a positive electrode terminal, a negative electrode terminal, and a plurality of elements. In FIG. 1, one battery module 4 in which a plurality of batteries 3 are connected in series is provided. However, the present invention is not limited thereto, but a plurality of battery modules may be provided. The plurality of battery modules may he connected in series or in parallel.

Hereinafter, the case where control apparatus 1 controls the adjustment discharge of the battery 3 in order to perform the refresh charge of another battery 3, corrects the estimated SOC, and estimates the degree of degradation will be described. Similarly, the control apparatus 1 can control the adjustment discharge and the refresh charge of battery module 4, correct the estimated SOC, and estimate the degree of degradation. The control apparatus 1 acquires history information such as a transition (temporal transition) of a current and a voltage of the adjustment discharge of the battery 3 from the battery control apparatus 2, corrects the estimated SOC of the battery 3, determines the degree of degradation of the battery 3, and transmits the obtained result to the battery control apparatus 2.

The control apparatus 1 includes a controller 11 that controls the entire apparatus, a main storage 12, a communication unit 13, an auxiliary storage 14, and a clocking unit 15. The control apparatus 1 can be configured of one or a plurality of servers. The control apparatus 1 may use a virtual machine as well as a plurality of apparatuses for distributed processing.

The controller 11 can be configured of a central processing unit (CPU), a read only memory (ROM), a random access memory (RAM), and the like. The controller 11 may include a graphics processing unit (CPU). In addition, a quantum computer may be used.

The main storage 12 is a temporary storage area such as a static random access memory (SRAM), a dynamic random access memory (DRAM), or a flash memory, and temporarily stores data required for the controller 11 to execute arithmetic processing.

The communication unit 13 has a function of communicating with the battery control apparatus 2 through the network N, and can transmit and receive required information. Specifically, the communication unit 13 receives the history information transmitted from the battery control apparatus 2. The communication unit 13 transmits the determination result of the degradation of the battery 3 to the battery control apparatus 2.

The auxiliary storage 14 is a large-capacity memory, a hard disk, or the like, and stores a program required for the controller 11 to execute processing, a program 141 performing adjustment discharge processing, a degradation history DB 142, a use history DB 143, and a relationship DB 144. The degradation history DB 142 may be stored in another DB server.

Table 1 illustrates an example of a table stored in the degradation history DB 142.

TABLE 1

| | Internal resistance (%) | | | Degradation |
|---|---|---|---|---|
| | First internal | Second internal | Third internal | (%) |
| No. | resistance | resistance | resistance | level |
| 1 | 100 | 100 | 100 | 0 |
| 2 | 114 | 112 | 116 | 80 |
| 3 | 159 | 157 | 160 | 100 |
| . . . | . . . | . . . | . . . | . . . |

The degradation history DB 142 stores a number column, internal resistance columns of a first internal resistance column, a second internal resistance column, and a third internal resistance column, and the degradation level column for each of the plurality of reached estimated SOCs. The number column stores a row numbers when the degradation of the battery 3 is determined at different timings of the same battery 3 for a plurality of different batteries 3. The internal resistance column stores the first internal resistance, the second internal resistance, and the third internal resistance derived as described above. The internal resistance is represented by a ratio when the initial internal resistance of the battery 3 is 100%. The present invention is not limited to the case where all of the first internal resistance, the second internal resistance, and the third internal resistance are stored in the internal resistance column. The internal resistance column stores at least one of the first internal resistance, the second internal resistance, and the third internal resistance. In addition, other internal resistances described above may be stored.

Furthermore, conductance may be stored instead of storing the internal resistance.

The degree of degradation column stores the degradation level obtained by measurement. The degradation level corresponds to, for example, a state of health (SOH), and the degradation level of SOH 100% is set to 0% and the degradation level of SOH 0% is set to 100%. The SOH can be determined based on a characteristic expected for the battery 3. For example, using the usable period as a reference, the ratio of the usable period remaining at the time of evaluation may be determined as the SOH. Using the voltage during the normal temperature high rate discharge as a reference, the voltage during the normal temperature high rate discharge at the time of evaluation may be used for the evaluation of SOH. The degradation level when a capacity retention ratio becomes less than or equal to a threshold may be set to 100%. In any case, the state in which the function of the battery 3 is lost is indicated when the SOH is 0%, namely, when the degradation level is 100%.

The degradation history DB 142 may store the internal resistance and the degradation level for each model of the battery 3 and for each power storage system 20.

Table 2 illustrates an example of a table stored in the use history DB 143.

### [Table 2]

TABLE 2

| | Internal resistance (%) | | | Degradation |
|---|---|---|---|---|
| IDNo.1 | First internal | Second internal | Third internal | level |
| No. | resistance | resistance | resistance | (%) |
| 1 | 100 | 100 | 100 | 0 |
| 2 | 105 | 104 | 106 | 10 |
| . . . | . . . | . . . | . . . | . . . |
| 5 | | | | 50 |
| . . . | . . . | . . . | . . . | . . . |
| 10 | 159 | 157 | 160 | 100 |

The use history DB 143 stores the number column, the internal resistance columns of the first internal resistance column, the second internal resistance column, and the third internal resistance column and the degradation level column for each of the plurality of estimated SOCs for each battery 3. Table 2 illustrates a use history of the battery 3 of ID No. 1. The internal resistance columns of the first internal resistance column, the second internal resistance column, and the third internal resistance column and the degradation level column store the same contents as those of the internal resistance columns of the first internal resistance column, the second internal resistance column, and the third internal resistance column and the degradation level column of the degradation history DB 142.

The internal resistance column stores the first internal resistance, the second internal resistance, and the third internal resistance derived as described above. The present invention is not limited to the case where all of the first internal resistance, the second internal resistance, and the third internal resistance are stored in the internal resistance column. The internal resistance column stores at least one of the first internal resistance, the second internal resistance, and the third internal resistance. In addition, other internal resistances described above may be stored.

Furthermore, conductance may be stored instead of storing the internal resistance.

The degree of degradation column stores the degradation level estimated as described later.

The relationship DB 144 stores a regression equation of the discharge curve and a relationship (degradation level curve) between the degradation level and the internal resistance obtained for each of the plurality of estimated SOCs. The discharge curve is used to correct the estimated SOC sequentially calculated using the charge-discharge capacity by, for example, a current integration method. Examples of the regression equation include a regression equation Y=aX+b+c/(X−d) of the discharge curve described in JP-A-11-121049. For example, the degradation level curve is derived for each model of the battery 3 based on the internal resistance and the degradation level stored in the degradation history DB 142.

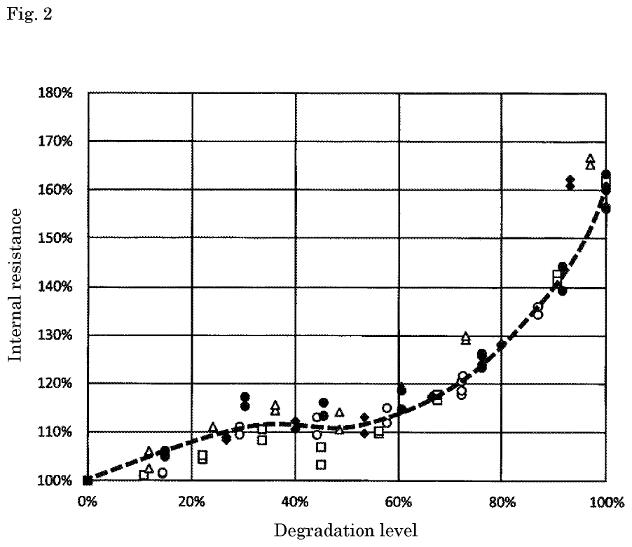

FIG. 2 illustrates an example of the degradation level curve when the estimated SOC is 30%. A horizontal axis represents the degradation level (%), and a vertical axis represents the ratio (%) of the internal resistance when the internal resistance of the initial battery is set to 100%.

The relationship may be table data.

A program 141 stored in the auxiliary storage 14 may be provided by a recording medium 140 in which the program 141 is readably recorded. For example, the recording medium 140 is a portable memory such as a USB memory, an SD card, a micro SD card, and a compact flash (registered trademark). The program 141 recorded on the recording medium 140 is read from the recording medium 140 using a reading device (not illustrated) and installed in the auxiliary storage 14. The program 141 may be provided by communication through the communication unit 13.

The clocking unit 15 performs clocking.

The power storage system 20 supplies the power to a thermal power generating system, a mega solar power generating system, a wind power generating system, a UPS, a stabilized power storage system for a railway, and the like, and stores the power generated in these systems.

The power storage system 20 includes the battery control apparatus the battery module 4, a temperature sensor 7, and a current sensor 8.

The battery control apparatus 2 includes a controller 21, a storage 22, a display panel 25, a clocking unit 26, an input unit 27, a communication unit 28, and an operation unit 29.

A load 19 is connected to the battery module 4 through terminals 17, 18.

The controller 21 includes, for example, a CPU, a ROM, a RAM, and the like, and controls the operation of the battery control apparatus 2.

The controller 21 monitors the state of each battery 3.

The controller 21 includes a voltage sensor that detects a voltage at each battery 3, a flyback or forward type converter, and the like, and controls the adjustment discharge and the refresh charge. When the controller 21 includes the flyback type converter, energy is stored in the primary-side winding of the transformer from the battery 3 in which the primary and secondary windings of the transformer are connected in reverse polarities, and the primary-side transistor is turned on to perform the adjustment discharge. After the primary-side transistor is turned off, the energy is released from the secondary-side winding of the transformer, and the charge energy is transferred to another battery 3. When the controller 21 includes the forward converter is provided, the power is transmitted to another battery 3 through the transformer during the discharge of the battery 3 that performs the adjustment discharge.

The storage 22 stores a program 23 required for the controller 21 to execute degradation determination processing and charge-discharge history data 24. The program 23 may be provided by a recording medium in which the program 23 is readably recorded.

The charge-discharge history is an operation history of the battery 3, and is information including information indicating a period (use period) during which the battery 3 performs the charge or the discharge, information about the charge or the discharge performed by the battery 3 during the use period, and the like. The information indicating the use period of the battery 3 is information including the start and end points of the charge or the discharge, an accumulated service period in which the battery 3 is used, and the like. The information about the charge or the discharge performed by the battery 3 is information indicating a voltage, a rate, or the like at the time of the charge or the discharge performed by the battery 3, a cumulative charge-discharge capacity, a history of the estimated SOC based on the cumulative charge-discharge capacity, or the like.

The display panel 25 can be configured of a liquid crystal panel, an organic electro luminescence (EL) display, or the like. The controller 21 performs control on display panel 25 in order to display the necessary information.

The clocking unit 26 performs clocking to count the timing of the adjustment discharge and the like.

The input unit 27 receives an input of the detection result from the temperature sensor 7 and the current sensor 8.

The communication unit 28 has a function of communicating with the control apparatus 1 through the network N, and can transmit and receive the necessary information.

The operation unit 29 includes, for example, a hardware keyboard, a mouse, a touch panel, and the like, and can perform operation of icons and the like displayed on the display panel 25, input of characters and the like, and the like.

The current sensor 8 is connected in parallel to the battery module 4, and outputs the detection result corresponding to the current of the battery module 4.

For example, the temperature sensor 7 outputs the detection result corresponding to the temperature of an installation place of the battery module 4.

The adjustment discharge of the battery 3 and the refresh charge of another battery 3, the correction of the estimated SOC of the battery 3 that performs the adjustment discharge, and a method for estimating the degree of degradation will be described below.

The control apparatus 1 corrects the estimated SOC based on the transition data of the current and the voltage when the adjustment discharge is performed.

The estimated SOC is derived as follows.

An estimated SOC_{T1} after the discharge of an electric quantity Q1 [Ah] from a SOC_{T0} at a certain time point T0 of the battery having actual capacity Q0 [Ah] is calculated by the following equation.

SOC_{T1}=SOC_{T0}−Q1/Q0[%]

An estimated SOC_{T2} after the charge of electric quantity Q2 [Ah] from the SOC_{T1} is calculated by the following equation

SOC_{T2}=SOC_{T1}+Q2/Q0[%]=SOC_{T0}−Q1/Q0+Q2/Q0[%]

As described above, the controller 21 sequentially calculates the estimated SOC using the charge-discharge capacity.

However, when the SOC exceeds 100% by the charge, the electricity amount exceeding 100% is defined as an overcharge electricity amount, and the SOC range is always 0%≤SOC≤100%.

When the sequential estimated SOC is calculated in this manner, the estimated SOC needs to be corrected because an estimation error is accumulated due to a side reaction during the charge, a loss of an electric quantity due to self-discharge, a detection error of the current sensor 8, and the like. When the discharge is performed until the discharge voltage reaches the end voltage, the estimated SOC is reset to 0%.

The controller 11 derives a transition curve of the period of the adjustment discharge based on the transition of the current and the voltage at the time of the adjustment discharge acquired from the controller 21. The transition curve indicates a change in voltage with respect to the discharge capacity or the discharge time. When the discharge is performed at a constant current, the discharge capacity is calculated by multiplying the current by the discharge time. Based on the transition curve, a discharge curve (Q-V curve) or (T-V curve) is obtained by the regression equation. When the regression equation of Y is used, coefficients a, b, c, d are obtained based on the transition curve.

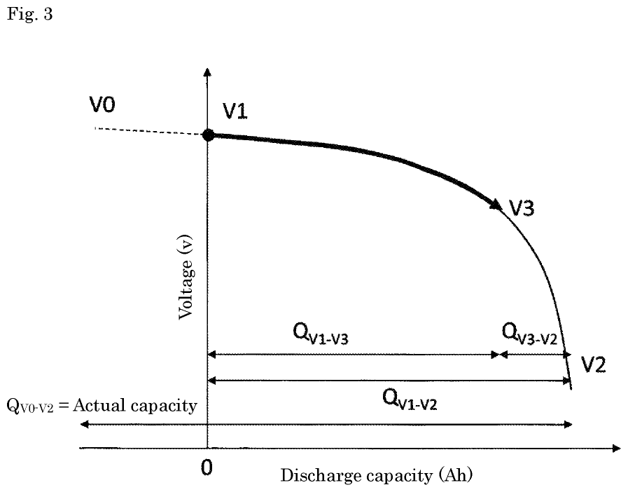

FIG. 3 illustrates the discharge curve. In FIG. 3, the horizontal axis indicates the discharge capacity (Ah), and the vertical axis indicates the voltage (V).

When the discharge is performed from the voltage V1 to the end voltage V2, the discharge curve is obtained by extrapolation based on the transition curve. An electric quantity Q_{V0-V2} corresponds to the actual capacity when the battery is discharged from the discharge starting voltage V0 to the end voltage V2 of the fully charged battery. The actual capacity Q_{V0-V2} may be derived by obtaining the discharge curve by the extrapolation using, for example, a regression equation for the transition curve after the latest refresh charge. The SOC at the time point V2 of the discharge curve is defined as 0%.

When the discharge is performed until the voltage becomes V3 from V1, the discharge curve from V1 to V2 is obtained by regression, and Q_{V1-V2} is obtained.

Because the SOC at the point V3 is a value obtained by dividing the electric quantity Q_{V3-V2} of V2 from V3 by the actual capacity Q_{V0-V2}, the SOC of V3 is calculated by the following equation.

SOC of V3=Q_{V3-V2}/Q_{V0-V2}−(Q_{V1-V2}−Q_{V1-V3})/Q_{V0-V2}

Q is calculated by multiplying the discharge current by time.

The regression equation is not limited to the equation of Y. In addition, the discharge curve may be obtained based on the transition curve by a least squares method or the like without storing the regression equation in the relationship DB 144.

The method for obtaining the residual capacity Q_{V3-V2} is not limited to the above case.

When the adjustment discharge is performed until the voltage becomes V2 from V1, the controller 11 resets the estimated SOC to 0% because the SOC is 0%.

When the adjustment discharge is performed until the voltage becomes V3 from V1, the controller 11 corrects the actually estimated SOC by the SOC (actually measured SOC) of V3. As described above, the estimated SOC is replaced with the actually measured SOC. Alternatively, the average value of the actually estimated SOC and the measured SOC is set to the updated SOC.

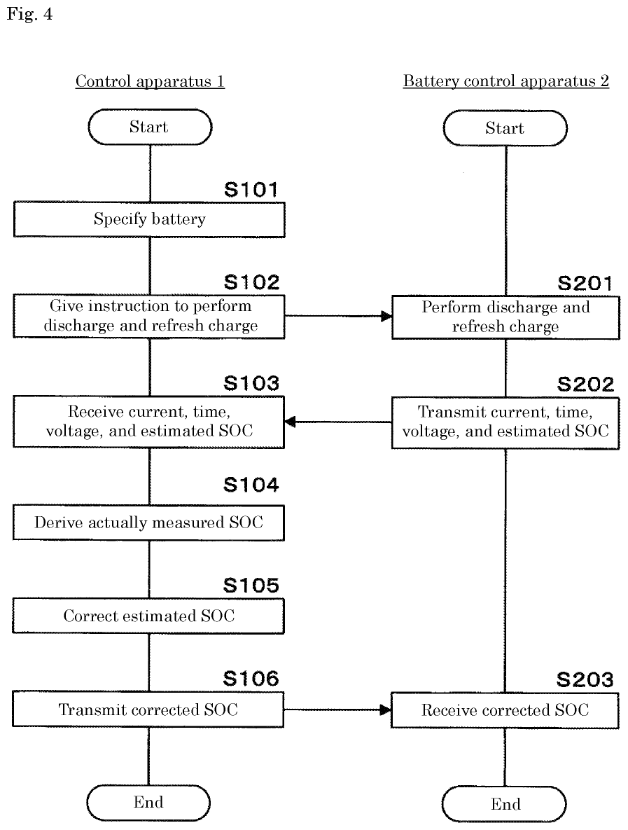

FIG. 4 is a flowchart illustrating a procedure of processing when the controller 11 performs the adjustment discharge on the battery 3, performs the refresh charge on another battery 3, and corrects the SOC.

The controller 11 specifies the battery 3 that performs the adjustment discharge and the battery 3 that performs the refresh charge using the power of the adjustment discharge (S101). The controller 11 specifies the battery 3 in which the estimated SOC is set to 100%, and specifies the battery 3 from which the power setting the estimated SOC of the battery 3 to 100% can be extracted.

The controller 11 performs the adjustment discharge of the battery 3, and transmits an instruction to perform the refresh charge to another battery 3 using the power of the adjustment discharge to controller 21 (S102).

The controller 21 performs the adjustment discharge on the battery 3 until the voltage at which the power that sets the estimated SOC of another battery 3 to 100% can be extracted, and performs the refresh charge on another battery 3 using the electric power (S201).

The controller 21 acquires the estimated SOC derived based on the adjusted discharge current, the voltage transition, and the integrated charge-discharge capacity from the history data 24, and transmits the estimated SOC to the control apparatus 1 (S202).

The controller 11 receives the current of the adjustment discharge, the voltage transition, and the estimated SOC (S103).

The controller 11 derives the measured SOC as described above (S104).

The controller 11 corrects the estimated SOC based on the actually measured SOC (S105).

When the actually measured SOC is 0%, the estimated SOC is set to 0%.

When the actually measured SOC is not 0%, for example, the controller 11 replaces the estimated SOC with the actually measured SOC. The controller 11 may set the average value of the estimated SOC and the actually measured SOC as the new SOC.

The controller 11 transmits a corrected SOC to battery control apparatus 2 (S106), and ends the processing.

The controller 21 receives the corrected SOC. Thereafter, the controller 21 estimates the SOC based on the corrected SOC (S203).

As described above, according to the first embodiment, the refresh charge of another battery 3 is performed using the power output when the battery 3 is discharged. The refresh charge can be performed without requiring external power. The power cost due to the refresh charge can be reduced, and the maintenance such as the refresh charge and the correction of the estimated SOC can be simultaneously performed even when the power storage system is independent from the power system.

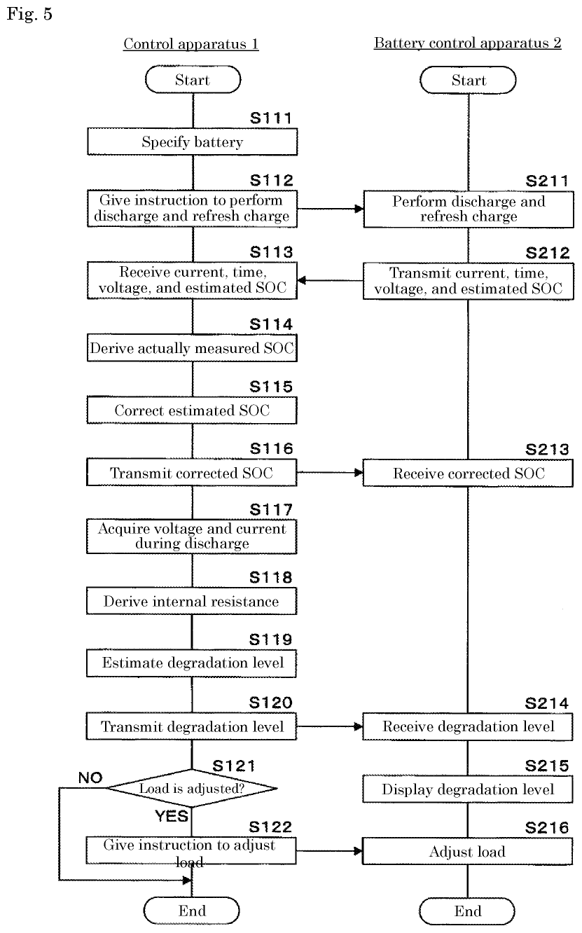

FIG. 5 is a flowchart illustrating a procedure of processing when the controller 11 performs the adjustment discharge on the battery 3, performs the refresh charge, and performs the correction of the SOC, estimation of the degradation level, and adjustment of the load.

The controller 11 specifies the battery 3 that performs the discharge and the battery 3 that performs the refresh charge using the discharge power (S111).

The controller 11 transmits an instruction to perform the adjustment discharge on the battery 3 and the charge another battery 3 using the discharge power at the same time to controller 21 (S112).

The controller 21 performs the adjustment discharge on the battery 3, and performs the refresh charge on another battery 3 using the discharge power (S211).

The controller 21 acquires the estimated SOC derived based on the discharge current, the transition of the voltage, and the integrated charge-discharge capacity from the history data 24, and transmits the estimated SOC to the control apparatus 1 (S212).

The controller 11 receives the discharge current, the transition of the voltage, and the reached estimated SOC (S113).

The controller 11 derives the actually measured SOC (S114).

The controller 11 calculates the estimated SOC (S115).

The controller 11 calculates the corrected SOC (S116).

The controller 21 calculates the corrected SOC (S213).

The controller 11 acquires the voltage and the current when the adjustment discharge is performed (S117). For example, when deriving the first internal resistance, the controller 11 acquires the voltage and the current immediately before and immediately after the end of the discharge.

The controller 11 derives the internal resistance as described above (S118).

The controller 11 estimates the degradation level and stores the degree of degradation in use history DB 143 (S119). The controller 11 reads the degradation level curve corresponding to the reached estimated SOC from the relationship DB 144, and reads the degradation level corresponding to the derived internal resistance. When the degradation level curve corresponding to the estimated SOC does not exist, the degradation level is obtained by interpolation calculation.

The controller 11 transmits the degradation level to the battery control apparatus 2 (S120).

The controller 21 receives the degradation level (S214).

The controller 21 displays the degradation level on the display panel 25 (S215).

The controller 11 determines whether to adjust the load (S121). For example, when the degradation level is greater than or equal to a threshold A or when the degradation level is less than or equal to a threshold B, the controller 11 determines that the load is adjusted. When the load is not adjusted (NO in S121), the processing ends.

When the degradation level is greater than or equal to the threshold A in adjusting the load (YES in S121), the controller 11 transmits an instruction to decrease the charge-discharge amount of the battery 3, decrease a frequency of the charge-discharge, or the like to the controller 21. When the degradation level is less than or equal to the threshold B, the controller 11 transmits an instruction to increase the charge-discharge amount of the battery 3, increase the frequency of the charge-discharge, or the like (S122), and ends the processing.

The controller 21 adjusts the load of the battery 3 (S205), and ends the processing. When not adjusting the load of the battery 3, the controller 21 ends the process after 5215.

FIG. 6 is a graph illustrating results of examining the internal resistance of each battery when batteries 1 to 6 with reduced capacities are deeply discharged until the estimated SOC reaches 30%. The vertical axis represents the ratio of the internal resistance when the internal resistance of the initial battery is 100%.

FIG. 7 is a graph illustrating results of examining the internal resistances of the batteries 1 to 6 with reduced capacities in the fully charged state. The vertical axis represents the ratio of the internal resistance when the internal resistance of the initial battery is 100%.

From FIGS. 6 and 7, it can be seen that the internal resistance in the case where the discharge is performed to the estimated SOC of 30% accurately reflects the decrease in capacity of the battery.

According to the first embodiment, the degree of degradation of the battery 3 in consideration of many degradation modes such as positive electrode softening, current collector corrosion, and electrolyte loss can be satisfactorily estimated based on the internal resistance when the adjustment discharge is performed.

When the load of the battery 3 is adjusted, a degradation rate of the battery 3 in the entire power storage system 20 can be uniformly maintained, the number of times of battery replacement can be reduced, and a risk that some batteries 3 are used beyond the use limit can be reduced.

The controller 21 may notify the operator of the power storage system 20 of the degradation level by voice instead of displaying the degradation level on the display panel 25.

In the first embodiment, the case where the control apparatus 1 controls the adjustment discharge and the refresh charge using the battery control apparatus 2 has been described, but the present invention is not limited thereto. Battery control apparatus 2 may perform the adjustment discharge and the refresh charge without being remotely operated by control apparatus 1.

In addition, the battery control apparatus 2 may derive the internal resistance and transmit the internal resistance to the control apparatus 1. The battery control apparatus 2 may correct the SOC of the battery 3 to estimate the degree of degradation of the battery 3.

### Second Embodiment

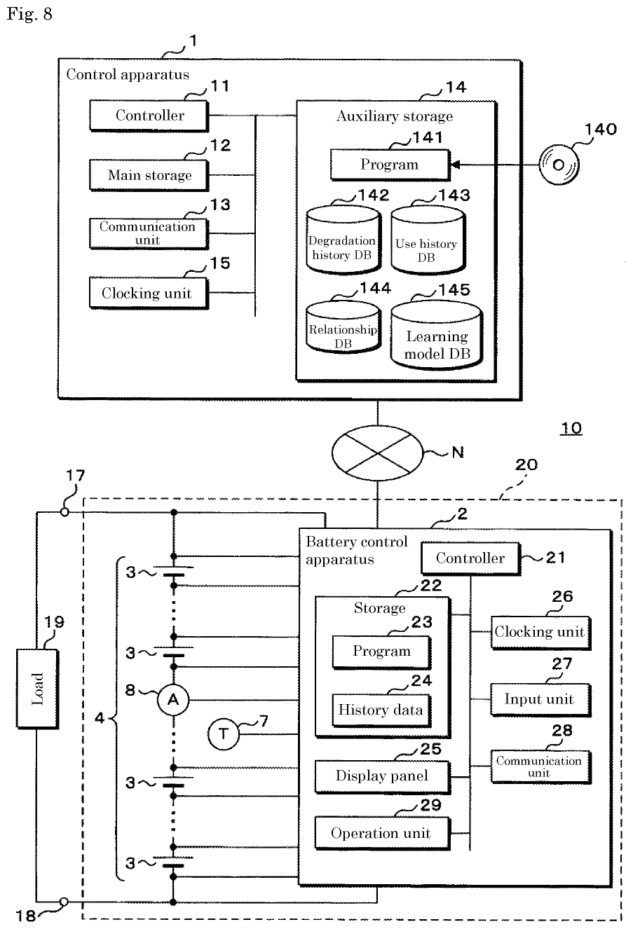

FIG. 8 is a block diagram illustrating a configuration of the degradation estimating system 10 according to a second embodiment.

The degradation estimating system 10 of the second embodiment has the same configuration as that of the degradation estimating system 10 of the first embodiment except that the auxiliary storage 14 stores the learning model DB 145. The learning model DB 145 stores a learning model 146 generated for each of the plurality of reached SOCs (estimated SOCs).

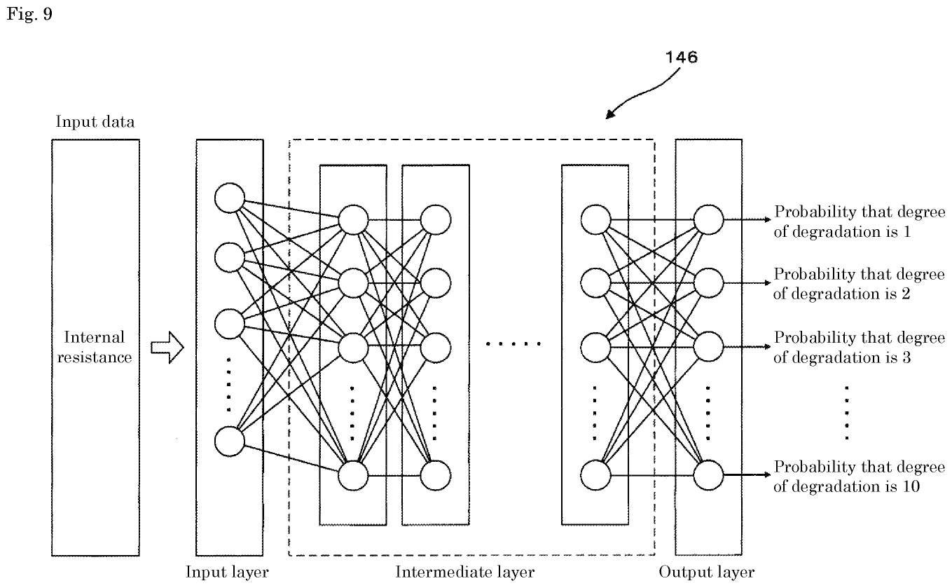

FIG. 9 is a schematic diagram illustrating an example of the learning model 146.

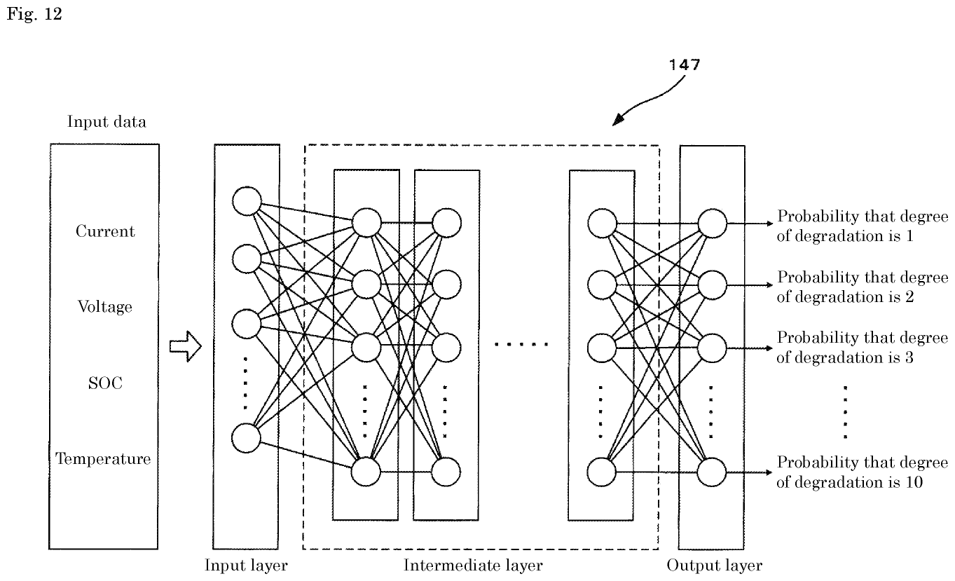

The learning model 146 is a learning model assumed to be used as a program module that is a part of artificial intelligence software, and a multilayer neural network (deep learning) can be used. For example, a convolutional neural network (CNN) can be used, and another neural network may be used. Another machine learning; may be used. The controller 11 operates to perform the operation on the internal resistance input to an input layer of the learning model 146 according to a command from the learning model 146, and output the degree of degradation and the probability thereof as a determination result. For the CNN, the intermediate layer includes a convolution layer, a pooling layer, and a fully connected layer. The number of nodes (neurons) is not limited to the case in FIG. 12.

The degree of degradation is indicated by, for example, a numerical value of 1 to 10 in 10 stages. The degree of degradation is determined based on the range of the degradation level. For example, “1” of the degree of degradation can be set in a range of 90% to 100% of the SOIL and “10” can be set in a range of 0 to 10% of the SOH.

One or a plurality of nodes (neurons) exist in the input layer, the output layer, and the intermediate layer, and the node of each layer is coupled to the nodes existing in the preceding and subsequent layers in one direction with a desired weight. A vector having components, the number of which is the same as the number of nodes of the input layer, is provided as input data (learning input data and estimation input data) of the learning model 146. The learned input data includes at least the internal resistance at the reached SOC. In addition to the internal resistance, the input data may include at least one of the internal resistance in the fully charged state, an open circuit voltage, the discharge capacity, the discharge voltage (an estimated value of the discharge capacity based on the discharge voltage), and a temperature obtained by the acquired temperature sensor 7.

The internal resistance is input to the input layer of the learned learning model 146. When the data given to each node of the input layer is input and given to the first intermediate layer, the output of the intermediate layer is calculated using the weight and the activation function, the calculated value is given to the next intermediate layer, and the calculated value is successively transmitted to the subsequent layer (lower layer) until the output of the output layer is obtained in the same manner. All of the weights coupling the nodes are calculated by a learning algorithm.

The output layer of the learning model 146 generates the degree of degradation and a probability thereof as output data.

The output layer is output as follows:

for example, the probability that the degree of degradation is 1 . . . 0.01

the probability that the degree of degradation is 2 . . . 0.90

the probability that the degree of degradation is 3 . . . 0.02

. . .

the probability that the degree of degradation is 1.0 . . . 0.001.

The controller 11 acquires the numerical value of the degree of degradation having the maximum probability.

Instead of the degree of degradation, the output layer may output the degradation level and its probability in increments of 1% in the range of, for example, 0% to 100%.

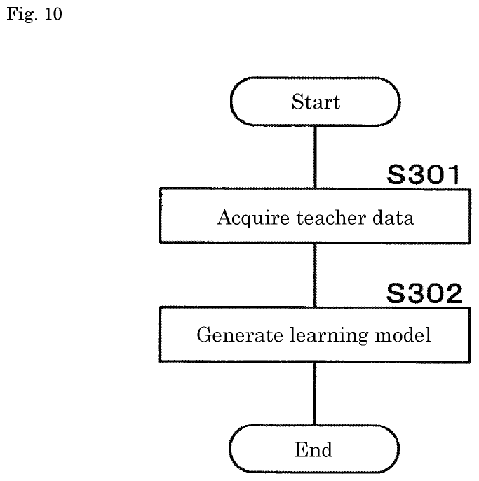

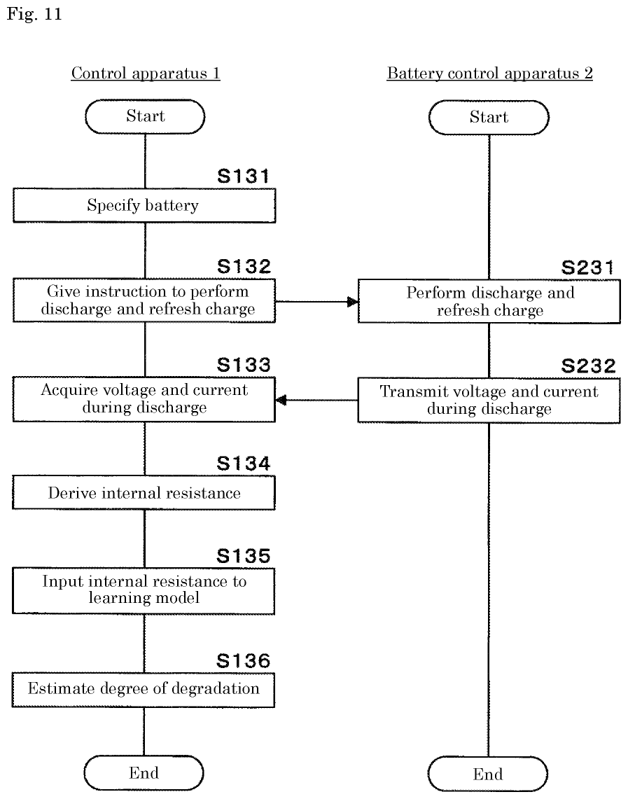

FIG. 10 is a flowchart illustrating a procedure of processing for generating the learning model 146 by the controller 11.

The controller 11 reads out the degradation history DB 142, and acquires teacher data in which the internal resistance of each row in a predetermined estimated SOC is associated with the degree of degradation based on the degradation level (S301).

The controller 11 uses the teacher data to generate the learning model 146 (learned model) that outputs the probability of the degree of degradation when the internal resistance is input (S302). Specifically, the controller 11 inputs the teacher data to the input layer, performs arithmetic processing in the intermediate layer, and acquires the probability of the degree of degradation from the output layer.

The controller 11 compares the determination result of the degree of degradation output from the output layer with information labeled with respect to the internal resistance in the teacher data, namely, a correct value, and optimizes the parameter used for the arithmetic processing in the intermediate layer such that the output value from the output layer approaches the correct value. For example, the parameter is the above-described weight (coupling coefficient), the coefficient of the activation function, or the like. The parameter optimization method is not particularly limited, but for example, the controller 11 optimizes various parameters using an error back propagation method.

The controller 11 stores the generated learning model 146 in the auxiliary storage 14, and ends the series of processing.

FIG. 11 is a flowchart illustrating a procedure of processing in which the controller 11 performs the adjustment discharge on the battery 3, performs the refresh charge, and estimates the degree of degradation of the battery 3.

The controller 11 specifies the battery 3 to be discharged and the battery 3 to be charged using the discharge power (S131).

The controller 11 transmits an instruction to perform the adjustment discharge on the battery 3 and charge another battery 3 using the discharge power at the same time to the controller 21 (S132).

The controller 21 performs the adjustment discharge on the battery 3, and charges another battery 3 using the discharge power (S231).

The controller 21 acquires the current and the voltage during the discharge from the history data 24, and transmits the acquired current and voltage to the control apparatus 1 (S232).

The controller 11 receives the current and the voltage (S133).

The controller 11 derives the internal resistance (S134).

The controller 11 selects the learning model 146 corresponding to the estimated SOC, and inputs the internal resistance to the learning model 146 (S135).

The controller 11 estimates the numerical value of the degree of degradation having the maximum probability output from the learning model 146 as the degree of degradation at the time of the current estimation (S136), and ends the processing.

After the estimation of the degree of degradation, the processing after S120 in FIG. 5 can be performed.

When the learning model 146 corresponding to the estimated SOC does not exist, the degree of degradation is estimated using the learning models 146 of two estimated SOCs close to the estimated SOC, and the degree of degradation is obtained by the interpolation calculation.

According to the second embodiment, the degree of degradation can be easily and accurately estimated.

The control apparatus 1 may correct the estimated SOC when acquiring the voltage and current during the discharge.

Although the case where the control apparatus 1 estimates the degree of degradation of the battery 3 has been described, the present invention is not limited thereto. The learning model 146 may be stored in the storage 22 of the battery control apparatus 2, and the battery control apparatus 2 may estimate the degree of degradation of the battery 3.

The controller 11 can cause the learning model 146 to be relearned such that reliability of the estimation of the degree of degradation is improved based on the degree of degradation estimated using the learning model 146 and the degree of degradation obtained by actual measurement in a predetermined row of the use history DB 35, the actually measured degradation level is obtained, and when the estimated degree of degradation is matched with the degree of degradation based on the actually measured degradation level, the probability of the degree of degradation can be increased by inputting and relearning a large number of teacher data in which the degree of degradation is associated with the internal resistance of this row. When the estimated degree of degradation is not matched with the actually measured degree of degradation, the teacher data in which the actually measured degree of degradation is associated with the internal resistance is input and the relearning is performed.

The learning model 146 may learn using the internal resistance at the reached SOC and the reached SOC and the label data indicating the degree of degradation as the teacher data, and output the degree of degradation when the internal resistance and the reached SOC are input in this case, a plurality of learning models are not required to be generated as described above.

### Third Embodiment

FIG. 12 is a schematic diagram illustrating an example of a learning model 147 according to a third embodiment.

The learning model 147 has the same configuration as that of the learning model 146 except that the input data is different from the input data of the learning model 146.

The current, the voltage, the SOC (reached estimated SOC), and the temperature are input to the input layer of the learned learning model 147. The current and the voltage are obtained when the adjustment discharge of the battery 3 is performed, and are the current and the voltage that, are used when the internal resistance is derived. When the data given to each node of the input layer is input and given to the first intermediate layer, the output of the intermediate layer is calculated using the weight and the activation function, the calculated value is given to the next intermediate layer, and the calculated value is successively transmitted to the subsequent layer (lower layer) until the output of the output layer is obtained in the same manner All of the weights coupling the nodes are calculated by a learning algorithm. The input data is not limited to the case of including all of the current, the voltage, the SOC, and the temperature. Another piece of information may be included. At least the current, the voltage, and the SOC are included. When the plurality of learning models is generated according to the plurality of SOCs as in the second embodiment, because the learning model corresponding to the SOC is selected, the SOC does not need to be input.

The output layer of the learning model 147 generates the degree of degradation and the probability thereof as the output, data.

The output layer is output as follows:

for example, the probability that the degree of degradation is 1 . . . 0.01

the probability that the degree of degradation is 2 . . . 0.90

the probability that the degree of degradation is 3 . . . 0.02

. . .

the probability that the degree of degradation is 10 . . . 0.001.

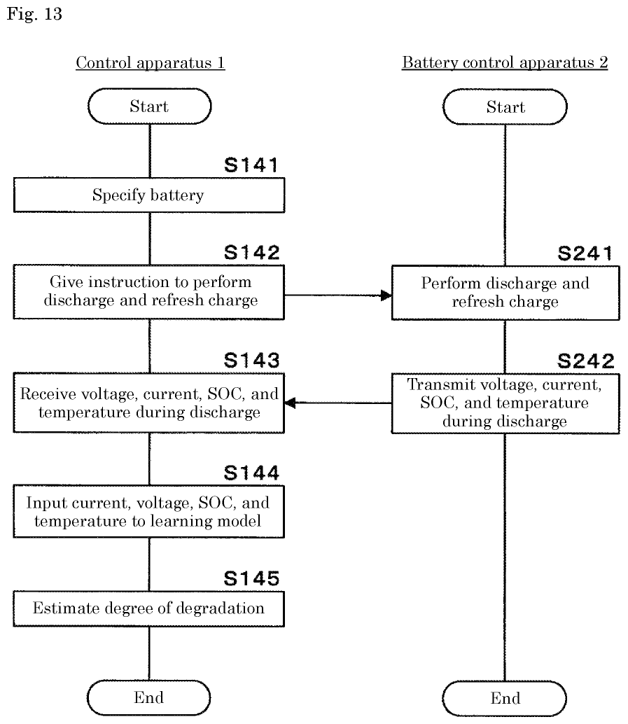

FIG. 13 is a flowchart illustrating a procedure of processing in which the controller 11 performs the adjustment discharge on the battery 3, performs the refresh charge, and estimates the degree of degradation.

The controller 11 specifies the battery 3 to be discharged and the battery 3 to he charged using the discharged power (S141).

The controller 11 transmits an instruction to perform the adjustment discharge on the battery 3 and charge another battery 3 using the discharge power at the same time to the controller 21 (S142).

The controller 21 performs the predetermined adjustment discharge on the battery 3, and charges another battery 3 with CMU 6 or 9 using the discharge power (S241).

The controller 21 acquires the current, the voltage, the SOC, and the temperature from the history data 24, and transmits the current, the voltage, the SOC, and the temperature to the control apparatus 1 (S242).

The controller 11 receives the current, the voltage, the SOC, and the temperature (S143).

The controller 11 inputs the current, the voltage, the SOC, and the temperature to the learning model 147 (S144).

The controller 11 determines the numerical value of the degree of degradation having the maximum probability output from the learning model 147 as the degree (S145), and ends the processing.

According to the second embodiment, the degree of degradation can be easily and accurately estimated.

The control apparatus 1 may correct the estimated SOC when acquiring the voltage and current during the discharge.

Although the case where the control apparatus 1 estimates the degree of degradation of the battery 3 has been described, the present invention is not limited thereto. The learning model 147 may be stored in the storage 22 of the battery control apparatus 2, and the battery control apparatus 2 may estimate the degree of degradation of the battery 3.

The present invention is not limited to the contents of the above embodiments, but various modifications can be made within the scope of the claims. That is, an embodiment obtained by combining technical means appropriately changed within the scope of the claims is also included in the technical scope of the present invention.

### DESCRIPTION OF REFERENCE SIGNS

1: control apparatus

2: battery control apparatus

3: lead-acid battery

4: lead-acid battery module

7: temperature sensor

8: current sensor

10: degradation estimating system

11: controller (charge controller, SOC correction unit, estimation unit, load adjustment unit)

12: main storage

13, 28: communication unit

14: auxiliary storage

141, 23: program

142: degradation history DB

143: use history DB

144: relationship DB

145: learning model DB

146, 147: learning model

20: power storage system

29: operation unit

1. A control apparatus comprising a charge controller that, by using power when a lead-acid battery or a lead-acid battery module including a plurality of lead-acid batteries is discharged, performs refresh charge of another lead-acid battery or another lead-acid battery module.

2. The control apparatus according to claim 1, further comprising an SOC correction unit that corrects an estimated value of an SOC of the lead-acid battery or the lead-acid battery module based on a residual capacity derived from a current and transition of a voltage when the lead-acid battery or the lead-acid battery module is discharged.

3. The control apparatus according to claim 1, further comprising an estimation unit that estimates a degree of degradation of the lead-acid battery or the lead-acid battery module based on an internal resistance or conductance derived in a case of the discharge.

4. The control apparatus according to claim 3, wherein the internal resistance is at least one of:
a first internal resistance derived based on a current and a voltage immediately before end of discharge and a current and a voltage immediately after end of discharge;
a second internal resistance derived based on a current and a voltage immediately before start of charge and a current and a voltage immediately after start of charge; and
a third internal resistance derived from a response when an AC voltage or an AC current is applied to a discharged lead-acid battery.

5. The control apparatus according to claim 3, wherein when the internal resistance or the conductance is input, the estimation unit inputs the internal resistance or a conductance of a target lead-acid battery or lead-acid battery module to a learning model that outputs a degree of degradation, and estimates a degree of degradation of the lead-acid battery or lead-acid battery module.

6. The control apparatus according to claim 3, wherein when a current and a voltage are input when the lead-acid battery or the lead-acid battery module is discharged, the estimation unit estimates a degree of degradation of the lead-acid battery or the lead-acid battery module by inputting the acquired current and voltage to a learning model that outputs a degree of degradation.

7. The control apparatus according to claim 3, further comprising a load adjustment unit that adjusts a load of the lead-acid battery or the lead-acid battery module according to the degree of degradation estimated by the estimation unit.

8. A degradation estimating system comprising:
the control apparatus according to claim 3; and
a terminal that transmits a current, a voltage, or the internal resistance to the control apparatus,
wherein the control apparatus transmits the degree of degradation estimated by the estimation unit to the terminal.

9. A control method for performing, by using power when a lead-acid battery or a lead-acid battery module including a plurality of lead-acid batteries is discharged, a refresh charge of another lead-acid battery or another lead-acid battery module.

10. A computer program causing a computer to execute processing for performing, by using power when a lead-acid battery or a lead-acid battery module including a plurality of lead-acid batteries is discharged, a refresh charge of another lead-acid battery or another lead-acid battery module.
